(19) United States
(12) Patent Application Publication
(10) Pub. No.: US 2024/0047270 A1
(43) Pub. Date: Feb. 8, 2024

(54) SEMICONDUCTOR STRUCTURE AND METHOD FOR MANUFACTURING THE SAME

(71) Applicant: TAIWAN SEMICONDUCTOR MANUFACTURING COMPANY LTD., HSINCHU (TW)

(72) Inventors: PEI-YU CHOU, HSINCHU CITY (TW); TSAI-JUNG HO, CHANGHUA COUNTY (TW); MENG-KU CHEN, NEW TAIPEI CITY (TW); TZE-LIANG LEE, HSINCHU (TW)

(21) Appl. No.: 17/817,025

(22) Filed: Aug. 3, 2022

(51) Int. Cl. H01L 21/768; H01L 23/522

(52) U.S. Cl. CPC H01L 21/76888; H01L 23/5226; H01L 21/76816; H01L 21/76826

(57) ABSTRACT

A semiconductor structure and a method of manufacturing the same are provided. The semiconductor structure includes a semiconductor substrate, a first patterned conductive layer, a second patterned conductive layer, a first dielectric layer, a third patterned conductive layer, a fourth patterned conductive layer, a second dielectric layer, and an oxide structure. The first dielectric layer is disposed on the semiconductor substrate and surrounds the first patterned conductive layer and the second patterned conductive layer. The third patterned conductive layer is disposed on the first patterned conductive layer. The fourth patterned conductive layer is disposed on the second patterned conductive layer. The second dielectric layer is disposed on the first dielectric layer. The oxide structure is in contact with the second dielectric layer, a side surface of the fourth patterned conductive layer, and a side surface of the third patterned conductive layer.

### TECHNICAL FIELD

The present disclosure relates, in general, to semiconductor structures and methods for manufacturing the same. Specifically, the present disclosure relates to semiconductor structures with oxide ring structures, and methods for manufacturing the same.

### BACKGROUND

A semiconductor structure may include multiple patterned conductive layers providing electrical connection. Crosslinking between the silicon-oxide-silicon structures may include defects in the dielectric layer and induce leakage between vias. To improve the dielectric layer and decrease the leakage, an improved structure of the dielectric layer is needed.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is diagram of a semiconductor structure in accordance with some embodiments of the present disclosure.

FIGS. 2A, 2B, 2C, 2D, 2E, 2F, 2G, and 2H illustrate a method for manufacturing the semiconductor structure in accordance with some embodiments of the present disclosure.

FIG. 3 is diagram of a semiconductor structure in accordance with some embodiments of the present disclosure.

FIGS. 4A, 4B, 4C, and 4D illustrate a method for manufacturing the semiconductor structure in accordance with some embodiments of the present disclosure.

FIG. 5 is diagram of a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

An interconnect link structure between the silicon structure or semiconductor structure may include some defects in the dielectric layer. The defects in the dielectric layer may cause a leakage between vias. An improved structure of the dielectric layer in the semiconductor structure is called for.

Some exemplary operations of semiconductor formation are disclosed as follows. An exemplary oxide ring structure is in contact with the dielectric layer 70. In some embodiments, the oxide ring structure is formed by oxidizing a portion of the dielectric layer. The oxidization of the dielectric layer is performed or treated by oxygen (O₂) plasma. The oxidization or treatment of O₂ plasma may cure the dangling bond of the dielectric layers and oxidize the dielectric layers to oxide ring structures. After the O₂ plasma treatment, the oxide ring structures and the side surface of the dielectric layers may have denser surface and can reduce leakage of the dielectric layer.

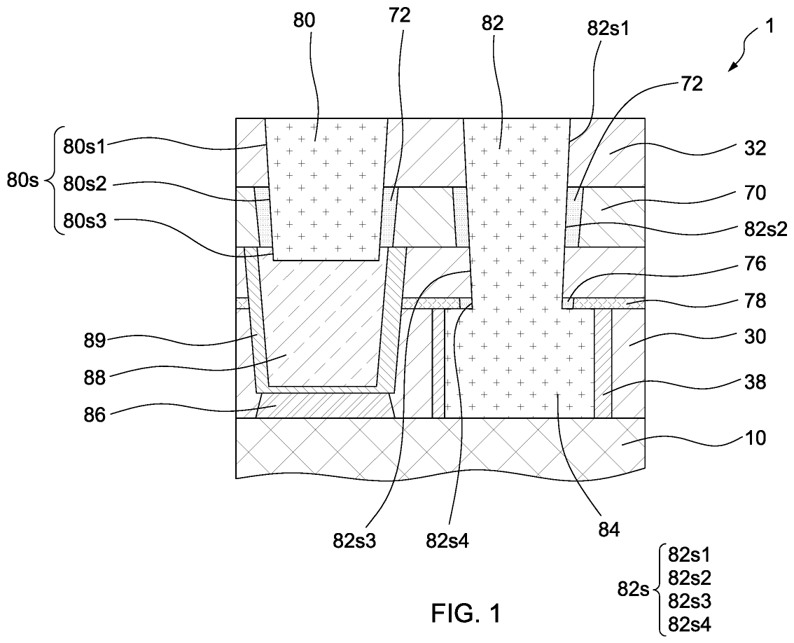

FIG. 1 is a diagram of a semiconductor structure 1 in accordance with some embodiments of the present disclosure. FIG. 1 shows a semiconductor structure 1. The semiconductor structure 1 includes a semiconductor substrate 10, a patterned conductive layer 84, a patterned conductive layer 88, a dielectric layer 30, a dielectric layer 32, patterned conductive layer 82, a patterned conductive layer 80, a dielectric layer 70, two oxide ring structures 72, an oxide ring structure 76, and a dielectric layer 78.

In some embodiments, the semiconductor substrate 10 includes several materials such as silicon, GaAs, germanium, silicon on insulator (SOI), or other suitable semiconductor materials. In some embodiments, in the semiconductor substrate 10 as shown, some features have been omitted for simplification. For example, the semiconductor substrate 10 may include transistors or other electric components such as resistors, diodes, etc.

The dielectric layer 30 is disposed on the semiconductor substrate 10. In some embodiments, the dielectric layers 30 and 32 include dielectric materials such as silicon oxide (SiO₂), SiOₓ, or other suitable materials. The dielectric layers 30 and 32 can be formed by various processes, such as chemical vapor deposition (CVD) or spin-coating. The dielectric layers 30 and 32 cover the semiconductor substrate 10 and provide electrical insulation between the semiconductor substrate 10 and overlaid conductive features.

The patterned conductive layer 84 is disposed on the semiconductor substrate 10. The patterned conductive layer 88 is disposed on the semiconductor substrate 10. In some embodiments, the dielectric layer 30 is disposed on the semiconductor substrate 10. The dielectric layer 30 surrounds the patterned conductive layer 84 and the patterned conductive layer 88. The patterned conductive layer 82 is disposed on the patterned conductive layer 84. The patterned conductive layer 80 is disposed on the patterned conductive layer 88. The dielectric layer 70 is disposed on the first dielectric layer 30. In some embodiments, the dielectric layer 70 is disposed on the patterned conductive layer 84 and the patterned conductive layer 88.

The oxide ring structure 72 is in contact with the dielectric layer 70. The oxide ring structure 72 is in contact with a portion of a side surface 80s of the patterned conductive layer 80. The oxide ring structure 72 is in contact with a portion of a side surface 82s of the patterned conductive layer 82. The oxide ring structure 72 is formed by oxidizing a side surface of the dielectric layer 70. In some embodiments, the oxide ring structure 72 is formed by oxidizing a portion of the dielectric layer 70. In some embodiments, the dielectric layer 78 is disposed in the dielectric layer 30. The dielectric layer 78 is disposed on the patterned conductive layer 84. The oxide ring structure 72 is in contact with a portion 82s2 of the side surface 82s of the patterned conductive layer 82. In some embodiments, the thickness of the oxide ring structures 72 and 76 is around 1 nanometer (nm) to 5 nm.

The oxide ring structure 76 is in contact with the dielectric layer 78. The oxide ring structure 76 is in contact with the side surface 82s of the patterned conductive layer 82. In some embodiments, the oxide ring structure 76 is in contact with a portion 82s4 of the side surface 82s of the patterned conductive layer 82. In some embodiments, the oxide ring structure 76 surrounds a portion 82s4 of the side surface 82s of the patterned conductive layer 82. The oxide ring structure 76 is formed by oxidizing the dielectric layer 78. In some embodiments, the oxide ring structure 76 is formed by oxidizing a side surface of the dielectric layer 78. The two oxide ring structures 72 are surrounded by the dielectric layer 70. In some embodiments, the dielectric layers 70 and 78 include dielectric materials such as silicon nitride (SiN), or other suitable materials. In some embodiments, the dielectric layers 70 and 78 may be a metal contact etching stop layer. In some embodiments, the oxide ring structures 72 and 76 include dielectric materials such as silicon oxide (SiO), SiOₓ, silanol (SiOH), or other suitable materials. In some embodiments, the conductive layer 86 is an epitaxy silicon layer or an epitaxy layer. The oxide ring structures 72 are formed by oxidizing the dielectric layer 70. The dielectric materials such as SiN of the dielectric layer 70 may be oxidized to be silicon oxide (SiO), SiOₓ, or silanol (SiOH). The oxidization of the dielectric layer 70 is performed or treated by O₂ plasma. The oxidization or treatment of O₂ plasma may cure the dangling bond of the dielectric layers 30 and 32 and oxidize the dielectric layers 70 and 78 to oxide ring structures 72 and 76. After the O₂ plasma treatment, the oxide ring structures 72 and 76 and the side surface of the dielectric layers 30 and 32 may have denser surface and reduce the leakage of the dielectric layer 30 and 32. The O₂ plasma treatment is performed using O₂, O₃, or N₂O. In some embodiments, the temperature for performing the O₂ plasma treatment is around 0° C. to 300° C. In some embodiments, the power for performing the O₂ plasma treatment is around 10 W to 1000 W. In some embodiments, the pressure for performing the O₂ plasma treatment is around 0.01 torr to 500 torr. The O₂ plasma treatment restores the film property of the side surface of the oxide ring structures 72 and 76 and the dielectric layer 30 and 32.

In some embodiments, an elevation level of a bottom surface of the patterned conductive layer 80 is lower than an elevation level of a top surface of the patterned conductive layer 88. In some embodiments, an elevation level of a bottom surface of the patterned conductive layer 80 is lower than an elevation level of a bottom end of the oxide ring structure 72. In some embodiments, an elevation level of a bottom end of the oxide ring structure 76 is aligned with an elevation level of a top surface of the patterned conductive layer 84.

In some embodiments, a portion 82s3 of the side surface 82s of the patterned conductive layer 82 is disposed between the portion 82s2 of the side surface 82s of the patterned conductive layer 82 and the portion 82s4 of the side surface 82s of the patterned conductive layer 82. The portion 82s3 of the side surface 82s of the patterned conductive layer 82 is surrounded by the dielectric layer 30. A patterned conductive layer 82 is disposed on the patterned conductive layer 84. A portion 82s2 of a side surface 82s of the patterned conductive layer 82 is surrounded by the oxide ring structure 72. A patterned conductive layer 80 is disposed on the patterned conductive layer 88. A portion 80s2 of a side surface 80s of the patterned conductive layer 80 is surrounded by the oxide ring structure 72.

A dielectric layer 32 is disposed on the dielectric layer 70. A portion 80s1 of the side surface 80s of the patterned conductive layer 80 is disposed above the portion 80s2 of the side surface 80s of the patterned conductive layer 80 is surrounded by the dielectric layer 32. A portion 82s1 of the side surface 82s of the patterned conductive layer 82 is disposed above the portion 82s2 of the side surface 82s of the patterned conductive layer 82 is surrounded by the dielectric layer 32 and a bottom end of the portion 82s1 of the side surface 82s of the patterned conductive layer 82 is aligned with a top end of the oxide ring structure 72.

A lateral width of the oxide ring structure 72 is less than a lateral width of the patterned conductive layer 84. A lateral width of the oxide ring structure 72 is less than a lateral width of the patterned conductive layer 88. In some embodiments, a maximum outer diameter of the oxide ring structure 72 is less than a lateral width of the patterned conductive layer 84. A maximum outer diameter of the oxide ring structure 72 is less than a lateral width of the patterned conductive layer 88.

In some embodiments, the patterned conductive layer 88 includes a metal material such as cobalt (Co) or other suitable materials. The patterned conductive layer 88 includes a barrier layer 89 in contact with the patterned conductive layer 88. In some embodiments, the barrier layer 89 includes tantalum (Ta), tantalum nitride (TaN), titanium (Ti), titanium nitride (TiN), or other suitable materials. In some embodiments, the patterned conductive layer 84 includes a barrier layer 38 in contact with the patterned conductive layer 84. In some embodiments, the barrier layer 38 includes SiCN, SiCO, a spin-on low-k dielectric material such as SiLK™, etc, or other suitable materials. In some embodiments, the patterned conductive layers 80, 82 and 84 include metal materials such as tungsten (W), aluminum (Al), copper (Cu), or an alloy thereof (such as AlCu), or other suitable materials.

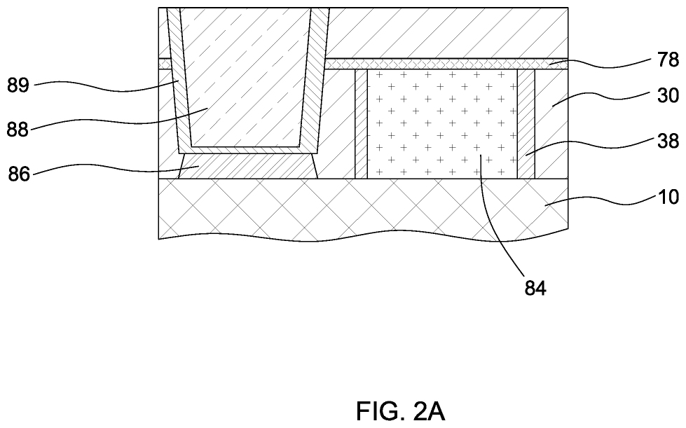

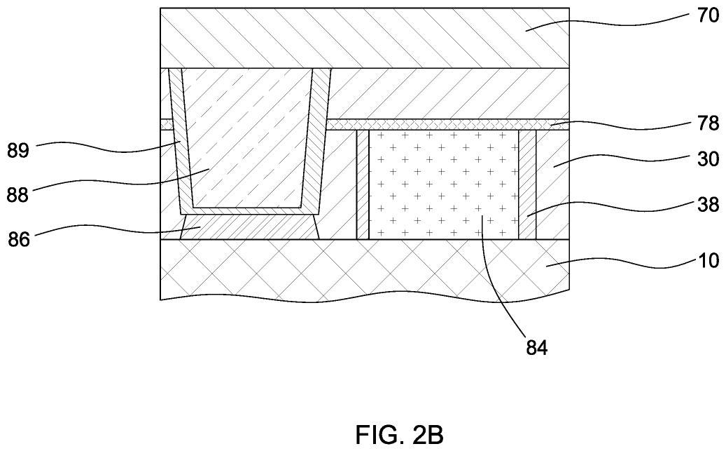

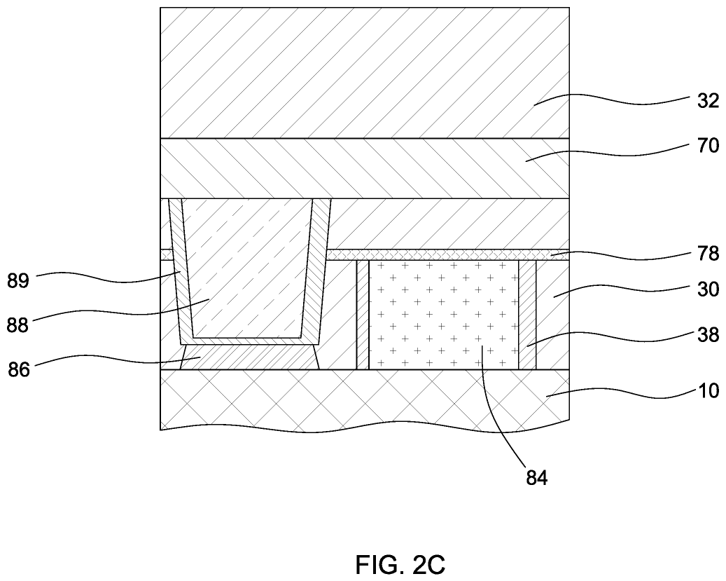

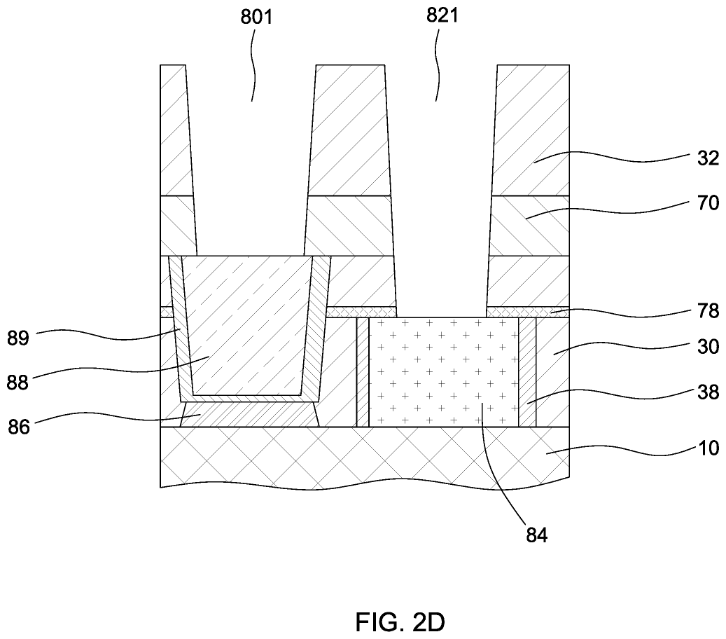

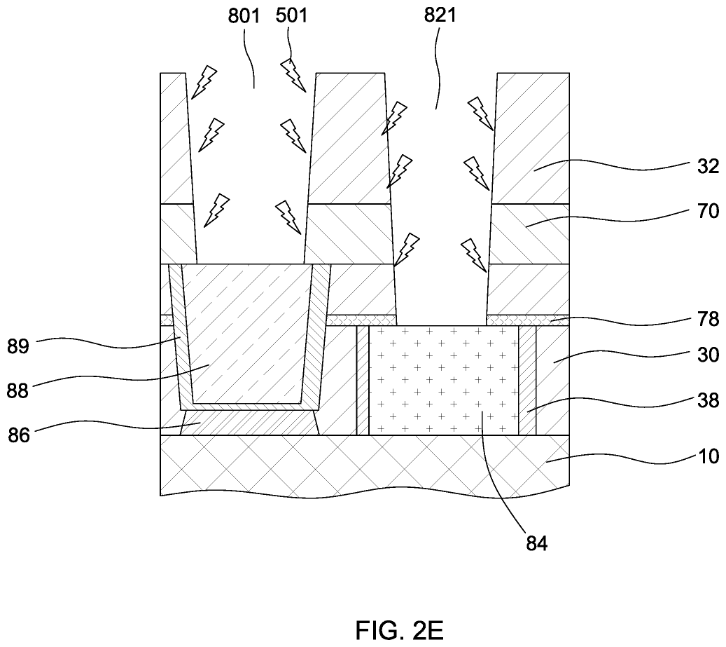

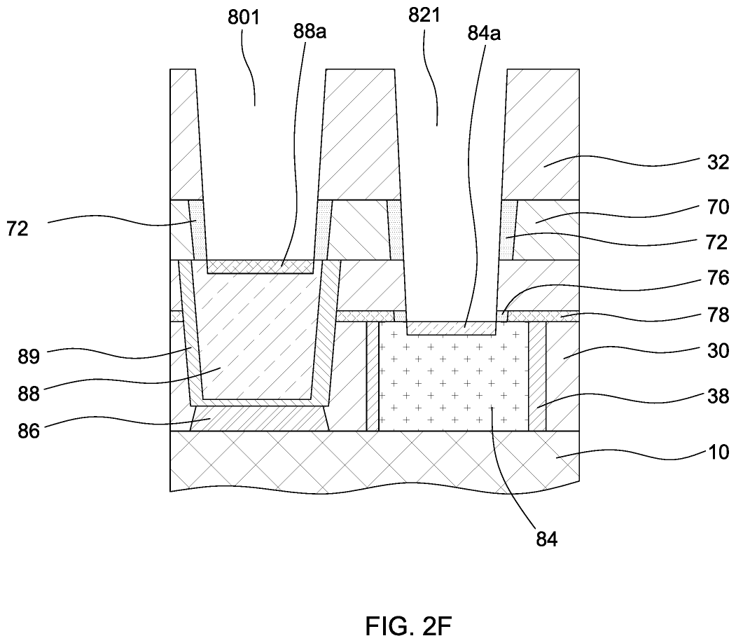

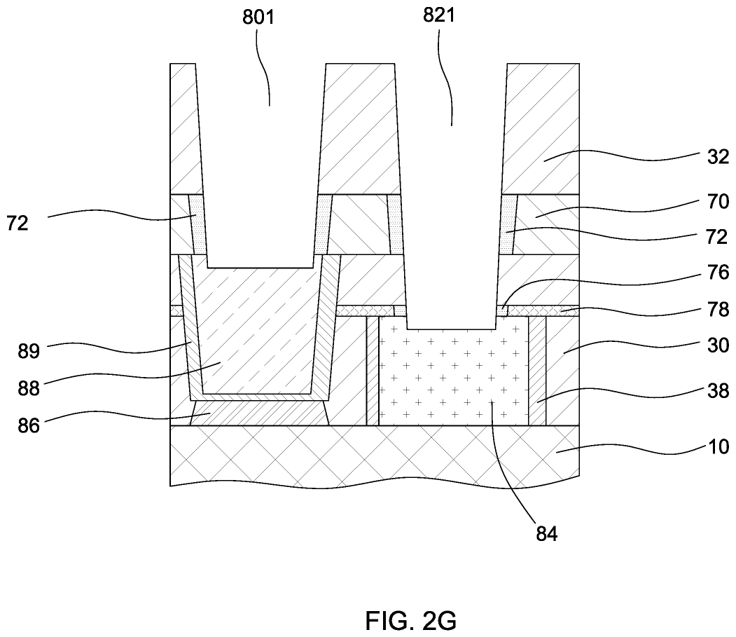

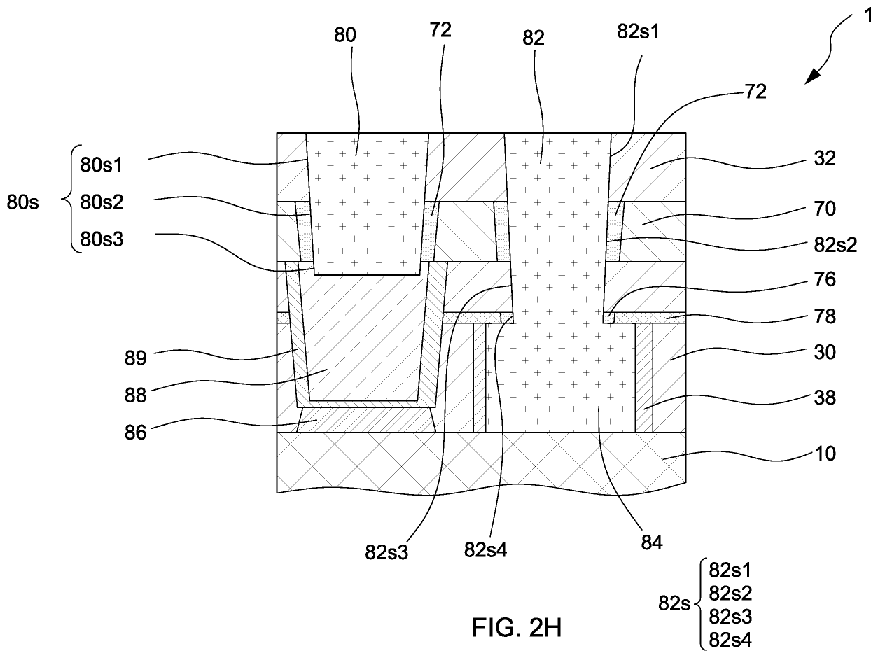

FIGS. 2A, 2B, 2C, 2D, 2E, 2F, 2G, and 2H illustrate a method for manufacturing the semiconductor structure 1 shown in FIG. 1, in accordance with some embodiments of the present disclosure. Referring to FIG. 2A, a semiconductor substrate 10, a patterned conductive layer 84, a patterned conductive layer 88, and a dielectric layer 30 are provided. In some embodiments, the semiconductor substrate 10 includes materials such as silicon, GaAs, germanium, silicon on insulator (SOI) or other suitable semiconductor materials. In some embodiments, in the semiconductor substrate 10 as shown, some features have been omitted for simplification. For example, the semiconductor substrate 10 may include transistors or other electric components such as resistors, diodes, etc. The dielectric layer 30 is disposed on the semiconductor substrate 10. In some embodiments, the dielectric layer 30 includes dielectric materials such as SiO₂, SiOₓ, or other suitable materials. The dielectric layer 30 can be formed by various processes, such as CVD or spin-coating. The dielectric layer 30 covers the semiconductor substrate 10 and provides electrical insulation between the semiconductor substrate 10 and overlaid conductive features. The patterned conductive layer 84 and the patterned conductive layer 88 is formed in the dielectric layer 30. In some embodiments, the conductive layer 86 is formed on the semiconductor substrate 10. In some embodiments, the conductive layer 86 is an epitaxy silicon layer or an epitaxy layer. The patterned conductive layer 88 is formed on the conductive layer 86. In some embodiments, the patterned conductive layer 88 includes a metal material such as Co or other suitable materials. The patterned conductive layer 88 includes a barrier layer 89 in contact with the patterned conductive layer 88. In some embodiments, the barrier layer 89 includes Ta, TaN, Ti, TiN, or other suitable materials. In some embodiments, the patterned conductive layer 84 includes a barrier layer 38 in contact with the patterned conductive layer 84. In some embodiments, the barrier layer 38 includes SiCN, SiCO, a spin-on low-k dielectric material such as SiLK™, etc, or other suitable materials. In some embodiments, the patterned conductive layer 84 includes metal materials such as W, Al or Cu, or an alloy thereof (such as AlCu), or other suitable materials. In some embodiments, the dielectric layer 78 is disposed in the dielectric layer 30. The dielectric layer 78 is disposed on the patterned conductive layer 84. In some embodiments, the dielectric layer 78 includes dielectric materials such as SiN, or other suitable materials. In some embodiments, the barrier layer 89 surrounds the patterned conductive layer 88.

Referring to FIG. 2B, a dielectric layer 70 is disposed on the dielectric layer 30. In some embodiments, the dielectric layer 70 is disposed on the patterned conductive layer 84 and the patterned conductive layer 88. The dielectric layer 70 is in contact with the patterned conductive layer 88 and dielectric layer 30. In some embodiments, the dielectric layer 70 includes dielectric materials such as SiN, or other suitable materials. In some embodiments, the dielectric layers 70 and 78 may be a metal contact etching stop layer.

Referring to FIG. 2C, a dielectric layer 32 is disposed on the dielectric layer 70. The dielectric layer 32 is in contact with the dielectric layer 70. In some embodiments, the dielectric layer 32 includes dielectric materials such as SiO₂, SiOₓ, or other suitable materials. The dielectric layer 32 can be formed by various processes, such as CVD or spin-coating. The dielectric layer 32 covers the dielectric layer 70 and provides electrical insulation between the semiconductor substrate 10, the dielectric layer 70, and overlaid conductive features.

Referring to FIG. 2D, a trench 801 and a trench 821 are formed in the dielectric layer 32 and the dielectric layer 70. The trench 801 and the trench 821 are formed by an etching operation. The trench 801 penetrates the dielectric layer 32 and the dielectric layer 70. The trench 821 penetrates the dielectric layer 32, the dielectric layer 70, and a portion of the dielectric layer 30. After forming the trench 801 and the trench 821, a top surface of the patterned conductive layer 84 is exposed and a top surface of the patterned conductive layer 88 is exposed. A side surface of the dielectric layer 32 and a side surface of the dielectric layer 70 are exposed. A side surface of the dielectric layer 30 is exposed and a side surface of the dielectric layer 78 is exposed.

Referring to FIG. 2E, an oxidization or treatment of O₂ plasma 501 is performed. The oxidization of the dielectric layer 70 is performed or treated by O₂ plasma. The oxidization or treatment of O₂ plasma may cure the dangling bond of the dielectric layers 30 and 32. The oxidization or treatment of O₂ plasma may oxidize the dielectric layers 70 and 78. After the O₂ plasma treatment, the side surface of the dielectric layers 30 and 32 may have denser side surfaces and reduce the leakage of the dielectric layer 30 and 32. In some embodiments, the O₂ plasma treatment is performed using O₂, O₃, or N₂O. In some embodiments, the temperature for performing the O₂ plasma treatment is around 0° C. to 300° C. In some embodiments, the power for performing the O₂ plasma treatment is around 10 W to 1000 W. In some embodiments, the pressure for performing the O₂ plasma treatment is around 0.01 torr to 500 torr. The O₂ plasma treatment restores the film property of the side surface of the dielectric layer 30 and 32. The O₂ plasma treatment may oxidize an exposed top surface of the patterned conductive layer 84 and an exposed top surface of the patterned conductive layer 88.

Referring to FIG. 2F, after the O₂ plasma treatment, the oxide ring structures 72 and 76 are formed by oxidizing a side surface of the trench 801 and a side surface of the trench 821. The oxide ring structure 72 is formed by oxidizing the dielectric layer 70. The oxide ring structure 76 is formed by oxidizing the dielectric layer 78. After the O₂ plasma treatment, the side surface of the dielectric layers 30 and 32 may have denser side surfaces and reduce the leakage of the dielectric layer 30 and 32. The O₂ plasma treatment restores the film property of the side surface of the oxide ring structures 72 and 76 and the dielectric layer 30 and 32. The O₂ plasma treatment oxidizes an exposed top surface of the patterned conductive layer 84 to form an oxide layer 84a and oxidizes an exposed top surface of the patterned conductive layer 88 to form an oxide layer 88a. In some embodiments, the oxide layer 88a includes a metal oxide such as CoOₓ or other suitable materials. In some embodiments, the oxide layer 84a includes a metal oxide such as tungsten oxide, aluminum oxide or cooper oxide, or other suitable materials.

Referring to FIG. 2G, a via pre-cleaning treatment is performed. The via pre-cleaning treatment is performed using Ar or H₂ plasma treatment. After the via pre-cleaning treatment, the metal oxides of the oxide layer 88a and the oxide layer 84a can be removed by the plasma operation. After the via pre-cleaning treatment, elevation of the exposed top surface of the patterned conductive layer 88 is lower than the elevation of the top surface of the dielectric layer 30, and elevation of the exposed top surface of the patterned conductive layer 84 is lower than the elevation of the bottom surface of the dielectric layer 78. The elevation level of the exposed top surface of the patterned conductive layer 88 is lower than the elevation of the bottom surface of the dielectric layer 70.

Referring to FIG. 2H, a patterned conductive layer 80 is formed in the trench 801 and a patterned conductive layer 82 is formed in the second trench 821. In some embodiments, the patterned conductive layers 80 and 82 include metal materials such as W, Al or Cu, or an alloy thereof (such as AlCu), or other suitable materials. After the patterned conductive layer 80 and the patterned conductive layer 82 are formed, the semiconductor structure 1 is obtained.

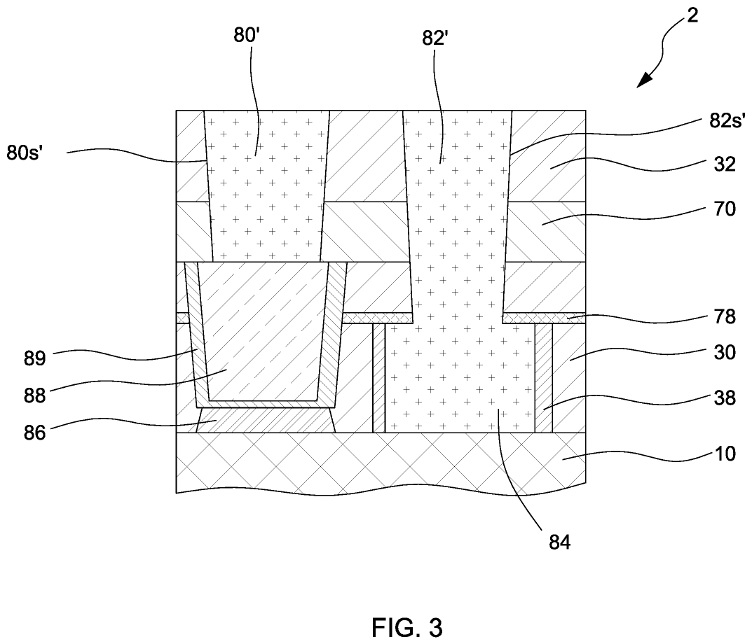

FIG. 3 is a diagram of a semiconductor structure 2 in accordance with some embodiments of the present disclosure. FIG. 1 shows a semiconductor structure 2. The semiconductor structure 2 includes a semiconductor substrate 10, a patterned conductive layer 84, a patterned conductive layer 88, a dielectric layer 30, a dielectric layer 32, patterned conductive layer 82′, a patterned conductive layer 80′, a dielectric layer 70, and a dielectric layer 78.

In some embodiments, the semiconductor substrate 10 includes several materials such as silicon, GaAs, germanium, SOI or other suitable semiconductor materials. In some embodiments, in the semiconductor substrate 10 as shown, some features have been omitted for simplification. For example, the semiconductor substrate 10 may include transistors or other electric components such as resistors, diodes, etc. The dielectric layer 30 is disposed on the semiconductor substrate 10. The patterned conductive layer 84 is disposed on the semiconductor substrate 10. The patterned conductive layer 88 is disposed on the semiconductor substrate 10. In some embodiments, the dielectric layer 30 is disposed on the semiconductor substrate 10.

In some embodiments, the dielectric layers 30 and 32 include dielectric materials such as SiO₂, SiOₓ, or other suitable materials. The dielectric layers 30 and 32 can be formed by various processes, such as CVD or spin-coating. The dielectric layers 30 and 32 cover the semiconductor substrate 10 and provide electrical insulation between the semiconductor substrate 10 and overlaid conductive features. The dielectric layer 30 surrounds the patterned conductive layer 84 and the patterned conductive layer 88. The patterned conductive layer 82′ is disposed on the patterned conductive layer 84. The patterned conductive layer 80′ is disposed on the patterned conductive layer 88. The dielectric layer 70 is disposed on the first dielectric layer 30. In some embodiments, the dielectric layer 70 is disposed on the patterned conductive layer 84 and the patterned conductive layer 88. In some embodiments, the dielectric layer 78 is disposed in the dielectric layer 30. In some embodiments, the dielectric layer 78 is disposed on the patterned conductive layer 84.

In some embodiments, the dielectric layers 70 and 78 include dielectric materials such as SiN, or other suitable materials. In some embodiments, the dielectric layers 70 and 78 may be a metal contact etching stop layer. In some embodiments, the conductive layer 86 is an epitaxy silicon layer or an epitaxy layer. The dielectric materials such as SiN of the dielectric layer 70 may be oxidized to be SiO, SiOₓ, or SiOH.

In some embodiments, elevation of a bottom surface of the patterned conductive layer 80′ is aligned with the elevation of a top surface of the patterned conductive layer 88. In some embodiments, elevation of a bottom surface of the patterned conductive layer 80′ is lower than the elevation of a bottom end of the dielectric layer 70.

In some embodiments, a portion of the side surface 82s′ of the patterned conductive layer 82′ is surrounded by the dielectric layer 30. In some embodiments, a portion of the side surface 82s′ of the patterned conductive layer 82′ is surrounded by the dielectric layer 70. In some embodiments, a portion of the side surface 82s′ of the patterned conductive layer 82′ is surrounded by the dielectric layer 32. The patterned conductive layer 82′ is disposed on the patterned conductive layer 84. A patterned conductive layer 80′ is disposed on the patterned conductive layer 88. A portion of a side surface 80s′ of the patterned conductive layer 80′ is surrounded by the dielectric layer 32. A portion of a side surface 80s′ of the patterned conductive layer 80′ is surrounded by the dielectric layer 70. A dielectric layer 32 is disposed on the dielectric layer 70.

In some embodiments, the patterned conductive layer 88 includes a metal material such as Co or other suitable materials. The patterned conductive layer 88 includes a barrier layer 89 in contact with the patterned conductive layer 88. In some embodiments, the barrier layer 89 includes Ta, TaN, Ti, TiN, or other suitable materials. In some embodiments, the patterned conductive layer 84 includes a barrier layer 38 in contact with the patterned conductive layer 84. In some embodiments, the barrier layer 38 includes SiCN, SiCO, a spin-on low-k dielectric material such as SiLK™, etc, or other suitable materials. In some embodiments, the patterned conductive layers 80′, 82′ and 84 include metal materials such as W, Al or Cu, or an alloy thereof (such as AlCu), or other suitable materials.

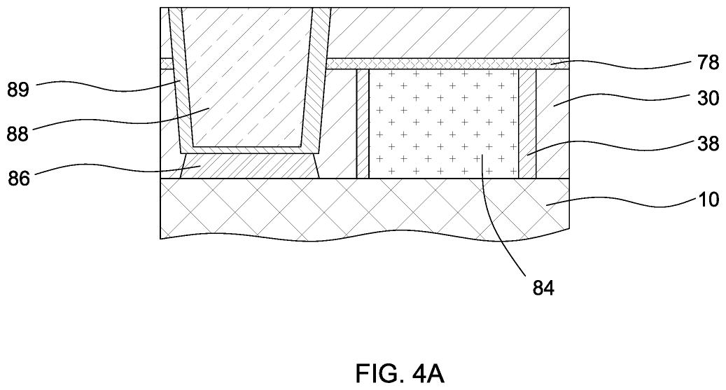

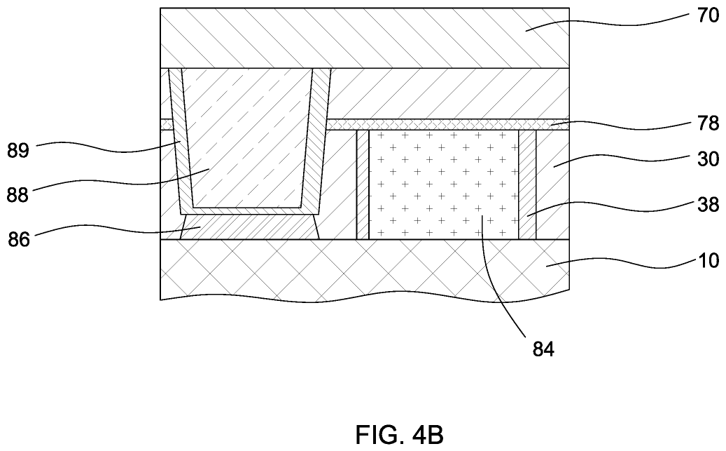

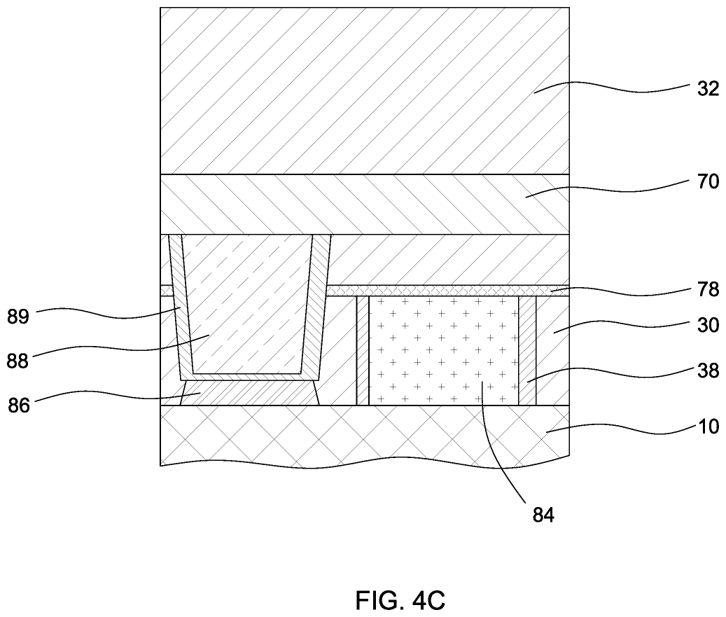

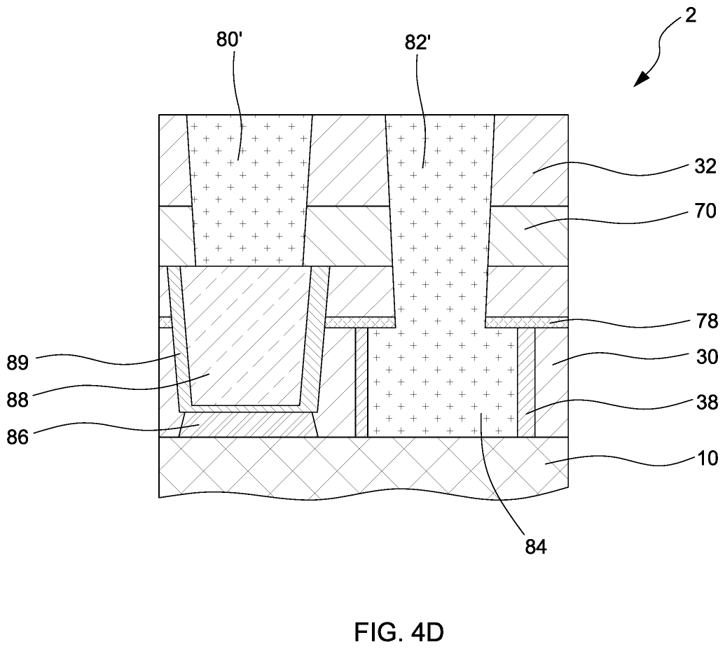

FIGS. 4A, 4B, 4C, and 4D illustrate a method for manufacturing the semiconductor structure 2 shown in FIG. 3, in accordance with some embodiments of the present disclosure. Referring to FIG. 4A, a semiconductor substrate 10, a patterned conductive layer 84, a patterned conductive layer 88, and a dielectric layer 30 are provided. In some embodiments, the semiconductor substrate 10 includes several materials such as silicon, GaAs, germanium, SOI or other suitable semiconductor materials. In some embodiments, in the semiconductor substrate 10 as shown, some features have been omitted for simplification. For example, the semiconductor substrate 10 may include transistors or other electric components such as resistors, diodes, etc. The dielectric layer 30 is disposed on the semiconductor substrate 10. In some embodiments, the dielectric layer 30 includes dielectric materials such as SiO₂, SiOₓ, or other suitable materials. The dielectric layer 30 can be formed by various processes, such as CVD or spin-coating. The dielectric layer 30 covers the semiconductor substrate 10 and provides electrical insulation between the semiconductor substrate 10 and overlaid conductive features. The patterned conductive layer 84 and the patterned conductive layer 88 are formed in the dielectric layer 30. In some embodiments, the conductive layer 86 is formed on the semiconductor substrate 10. In some embodiments, the conductive layer 86 is an epitaxy silicon layer or an epitaxy layer. The patterned conductive layer 88 is formed on the conductive layer 86. In some embodiments, the patterned conductive layer 88 includes a metal material such as Co or other suitable materials. The patterned conductive layer 88 includes a barrier layer 89 in contact with the patterned conductive layer 88. In some embodiments, the barrier layer 89 includes Ta, TaN, Ti, TiN, or other suitable materials. In some embodiments, the patterned conductive layer 84 includes a barrier layer 38 in contact with the patterned conductive layer 84.

In some embodiments, the barrier layer 38 includes SiCN, SiCO, a spin-on low-k dielectric material such as SiLK™, etc, or other suitable materials. In some embodiments, the patterned conductive layer 84 includes metal materials such as W, Al or Cu, or an alloy thereof (such as AlCu), or other suitable materials. In some embodiments, the dielectric layer 78 is disposed in the dielectric layer 30. The dielectric layer 78 is disposed on the patterned conductive layer 84. In some embodiments, the dielectric layer 78 includes dielectric materials such as SiN, or other suitable materials. In some embodiments, the barrier layer 89 surrounds the patterned conductive layer 88.

Referring to FIG. 4B, a dielectric layer 70 is disposed on the dielectric layer 30. In some embodiments, the dielectric layer 70 is disposed on the patterned conductive layer 84 and the patterned conductive layer 88. In some embodiments, the dielectric layer 70 includes dielectric materials such as SiN, or other suitable materials. In some embodiments, the dielectric layers 70 and 78 may be a metal contact etching stop layer. The dielectric layer 70 is in contact with the patterned conductive layer 88 and dielectric layer 30.

Referring to FIG. 4C, a dielectric layer 32 is disposed on the dielectric layer 70. The dielectric layer 32 is in contact with the dielectric layer 70. In some embodiments, the dielectric layer 32 includes dielectric materials such as SiO₂, SiOₓ, or other suitable materials. The dielectric layer 32 covers the dielectric layer 70 and provides electrical insulation between the semiconductor substrate 10, the dielectric layer 70, and overlaid conductive features. The dielectric layer 32 can be formed by various processes, such as CVD or spin-coating.

Referring to FIG. 4D, two trenches are formed in the dielectric layer 32 and the dielectric layer 70. The trenches are formed by an etching operation. After forming the trenches, a top surface of the patterned conductive layer 84 is exposed and a top surface of the patterned conductive layer 88 is exposed. A side surface of the dielectric layer 32 and a side surface of the dielectric layer 70 are exposed. A side surface of the dielectric layer 30 is exposed and a side surface of the dielectric layer 78 is exposed. A patterned conductive layer 80′ is formed in one trench and a patterned conductive layer 82′ is formed in another trench. In some embodiments, the patterned conductive layers 80′ and 82′ include metal materials such as W, Al or Cu, or an alloy thereof (such as AlCu), or other suitable materials. After the patterned conductive layer 80′ and the patterned conductive layer 82′ are formed, the semiconductor structure 2 is obtained.

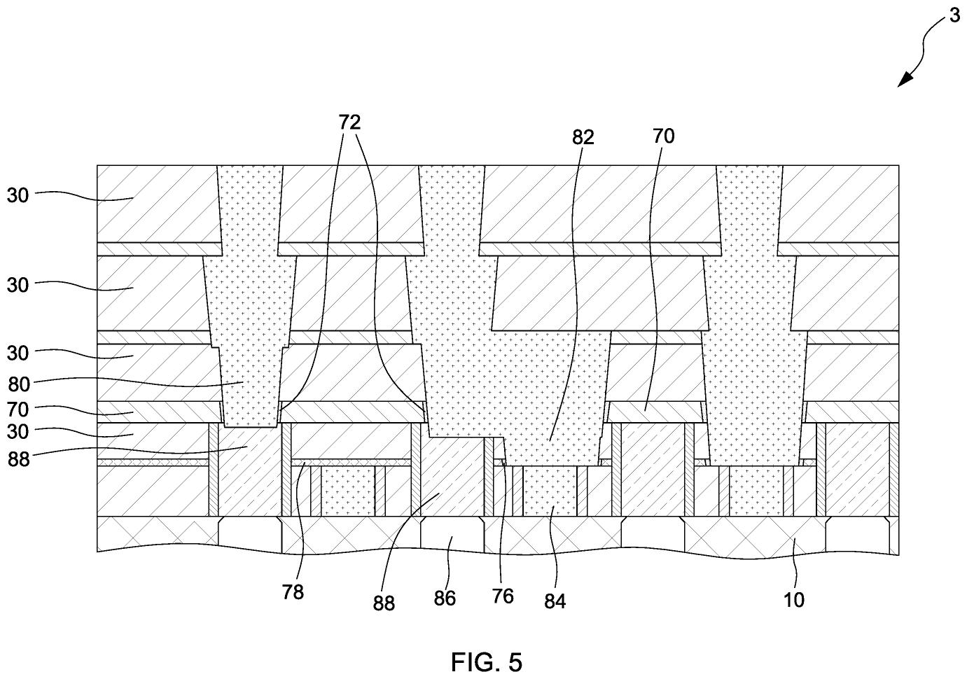

FIG. 5 is a diagram of a semiconductor structure 3 in accordance with some embodiments of the present disclosure. The semiconductor structure 3 includes the structure similar to the semiconductor structure 1 shown in FIG. 1. A semiconductor substrate 10 includes materials such as silicon, GaAs, germanium, SOI or other suitable semiconductor materials. In some embodiments, in the semiconductor substrate 10 as shown, some features have been omitted for simplification. For example, the semiconductor substrate 10 may include transistors or other electric components such as resistors, diodes, etc. The dielectric layer 30 is disposed on the semiconductor substrate 10. In some embodiments, the dielectric layer 30 includes dielectric materials such as SiO₂, SiOₓ, or other suitable materials. The dielectric layer 30 can be formed by various processes, such as CVD or spin-coating. The dielectric layer 30 covers the semiconductor substrate 10 and provides electrical insulation between the semiconductor substrate 10 and overlaid conductive features.

The oxide ring structure 72 is in contact with the dielectric layer 70. The oxide ring structure 72 is in contact with a portion of a side surface of the patterned conductive layer 80. The oxide ring structure 72 is in contact with a portion of a side surface 82s of the patterned conductive layer 82. The oxide ring structure 72 is formed by oxidizing a side surface of the dielectric layer 70. In some embodiments, the oxide ring structure 72 is formed by oxidizing a portion of the dielectric layer 70. In some embodiments, the dielectric layer 78 is disposed in the dielectric layer 30. The dielectric layer 78 is disposed on the patterned conductive layer 84. The oxide ring structure 72 is in contact with a portion of the side surface 82s of the patterned conductive layer 82. In some embodiments, the thickness of the oxide ring structures 72 and 76 is around 1 nm to 5 nm.

According to some embodiments, a semiconductor structure includes a semiconductor substrate, a first patterned conductive layer, a second patterned conductive layer, a first dielectric layer, a third patterned conductive layer, a fourth patterned conductive layer, a second dielectric layer, and an oxide structure. The first patterned conductive layer is disposed on the semiconductor substrate. The second patterned conductive layer is disposed on the semiconductor substrate. The first dielectric layer is disposed on the semiconductor substrate and surrounds the first patterned conductive layer and the second patterned conductive layer. The third patterned conductive layer is disposed on the first patterned conductive layer. The fourth patterned conductive layer is disposed on the second patterned conductive layer. The second dielectric layer is disposed on the first dielectric layer. The oxide structure is in contact with the second dielectric layer, a side surface of the fourth patterned conductive layer, and a side surface of the third patterned conductive layer.

According to other embodiments, a semiconductor structure includes a semiconductor substrate, a first patterned conductive layer, a second patterned conductive layer, a first dielectric layer, a second dielectric layer, first and second oxide ring structures, a third patterned conductive layer, and a fourth patterned conductive layer. The first patterned conductive layer is disposed on the semiconductor substrate. The second patterned conductive layer is disposed on the semiconductor substrate. A first dielectric layer is disposed on the semiconductor substrate and surrounds the first patterned conductive layer and the second patterned conductive layer. A second dielectric layer is disposed on the first patterned conductive layer and the second patterned conductive layer. First and second oxide ring structures are surrounded by the second dielectric layer. A third patterned conductive layer is disposed on the first patterned conductive layer. A first portion of a side surface of the third patterned conductive layer is surrounded by the first oxide ring structure. A fourth patterned conductive layer is disposed on the second patterned conductive layer. A first portion of a side surface of the fourth patterned conductive layer is surrounded by the second oxide ring structure. A lateral width of the first oxide ring structure is less than a lateral width of the first patterned conductive layer. A lateral width of the second oxide ring structure is less than a lateral width of the second patterned conductive layer.

According to other embodiments, a method for manufacturing a semiconductor structure includes forming a semiconductor substrate; forming a first dielectric layer on the semiconductor substrate, forming a first patterned conductive layer and a second patterned conductive layer in the first dielectric layer, forming a second dielectric layer on the first dielectric layer, forming a third dielectric layer on the second dielectric layer, forming a first trench and a second trench in the third dielectric layer, oxidizing a first side surface of the first trench and a second side surface of the second trench to form an oxide structure in contact with the second dielectric layer, and forming a fourth patterned conductive layer in the first trench and a third patterned conductive layer in the second trench.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods, and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A semiconductor structure comprising:
a semiconductor substrate;
a first patterned conductive layer disposed on the semiconductor substrate;
a second patterned conductive layer disposed on the semiconductor substrate;
a first dielectric layer disposed on the semiconductor substrate and surrounding the first patterned conductive layer and the second patterned conductive layer;
a third patterned conductive layer disposed on the first patterned conductive layer;
a fourth patterned conductive layer disposed on the second patterned conductive layer;
a second dielectric layer disposed on the first dielectric layer;
an oxide structure in contact with the second dielectric layer, a side surface of the fourth patterned conductive layer, and a side surface of the third patterned conductive layer.

2. The semiconductor structure of claim 1, wherein the oxide structure is formed by oxidizing the second dielectric layer.

3. The semiconductor structure of claim 1, further comprising a third dielectric layer disposed in the first dielectric layer; and a second oxide structure in contact with the third dielectric layer and the side surface of the third patterned conductive layer.

4. The semiconductor structure of claim 3, wherein the second oxide structure is formed by oxidizing the third dielectric layer.

5. The semiconductor structure of claim 1, wherein an elevation level of a bottom surface of the fourth patterned conductive layer is lower than an elevation level of a top surface of the second patterned conductive layer.

6. The semiconductor structure of claim 1, wherein an elevation level of a bottom surface of the fourth patterned conductive layer is lower than an elevation level of a bottom end of the oxide structure.

7. The semiconductor structure of claim 3, wherein an elevation level of a bottom end of the second oxide structure is aligned with an elevation level of a top surface of the first patterned conductive layer.

8. The semiconductor structure of claim 3, wherein a third portion of the side surface of the third patterned conductive layer is disposed between the first portion of the side surface of the third patterned conductive layer and the second portion of the side surface of the third patterned conductive layer, and wherein the third portion of the side surface of the third patterned conductive layer is surrounded by the first dielectric layer.

9. The semiconductor structure of claim 8, further comprising a third dielectric layer disposed on the second dielectric layer, wherein a second portion of the side surface of the fourth patterned conductive layer disposed above the first portion of the side surface of the fourth patterned conductive layer is surrounded by the third dielectric layer.

10. The semiconductor structure of claim 9, wherein a fourth portion of the side surface of the third patterned conductive layer disposed above the first portion of the side surface of the third patterned conductive layer is surrounded by the third dielectric layer, and wherein a bottom end of the fourth portion of the side surface of the third patterned conductive layer is aligned with a top end of the oxide structure.

11. A semiconductor structure comprising:
a semiconductor substrate;
a first patterned conductive layer disposed on the semiconductor substrate;
a second patterned conductive layer disposed on the semiconductor substrate;
a first dielectric layer disposed on the semiconductor substrate and surrounding the first patterned conductive layer and the second patterned conductive layer;
a second dielectric layer disposed on the first patterned conductive layer and the second patterned conductive layer;
first and second oxide ring structures surrounded by the second dielectric layer;
a third patterned conductive layer disposed on the first patterned conductive layer, wherein a first portion of a side surface of the third patterned conductive layer is surrounded by the first oxide ring structure;
a fourth patterned conductive layer disposed on the second patterned conductive layer, wherein a first portion of a side surface of the fourth patterned conductive layer is surrounded by the second oxide ring structure,
wherein a lateral width of the first oxide ring structure is less than a lateral width of the first patterned conductive layer, and a lateral width of the second oxide ring structure is less than a lateral width of the second patterned conductive layer.

12. The semiconductor structure of claim 11, wherein the first and second oxide ring structures are formed by oxidizing a portion of the second dielectric layer.

13. The semiconductor structure of claim 11, further comprising a third dielectric layer disposed in the first dielectric layer; and a third oxide ring structure surrounding a second portion of the side surface of the third patterned conductive layer.

14. The semiconductor structure of claim 13, wherein the third oxide ring structure is formed by oxidizing a portion of the third dielectric layer.

15. The semiconductor structure of claim 11, wherein an elevation level of a bottom surface of the fourth patterned conductive layer is lower than an elevation level of a top surface of the second patterned conductive layer.

16. The semiconductor structure of claim 11, wherein an elevation level of a bottom surface of the fourth patterned conductive layer is lower than an elevation level of a bottom end of the second oxide ring structure.

17. A method for manufacturing a semiconductor structure comprising:
forming a semiconductor substrate;
forming a first dielectric layer on the semiconductor substrate;
forming a first patterned conductive layer and a second patterned conductive layer in the first dielectric layer;
forming a second dielectric layer on the first dielectric layer;
forming a third dielectric layer on the second dielectric layer;
forming a first trench and a second trench in the third dielectric layer;
oxidizing a first side surface of the first trench and a second side surface of the second trench to form an oxide structure in contact with the second dielectric layer; and
forming a fourth patterned conductive layer in the first trench and a third patterned conductive layer in the second trench.

18. The method of claim 17, wherein oxidizing a first side surface of the first trench and a second side surface of the second trench further comprising oxidizing an exposed top surface of the first patterned conductive layer and an exposed top surface of the second patterned conductive layer.

19. The method of claim 18, further comprising removing an oxidized portion of the first patterned conductive layer and an oxidized portion of the second patterned conductive layer before forming the fourth patterned conductive layer in the first trench and the third patterned conductive layer in the second trench.

20. The method of claim 18, wherein oxidizing a first side surface of the first trench and a second side surface of the second trench further comprising oxidizing a third dielectric layer in the first dielectric layer to form a second oxide structure in contact with the third dielectric layer.
